(19) United States
(12) Patent Application Publication
(10) Pub. No.: US 2026/0181894 A1
(43) Pub. Date: Jun. 25, 2026

(54) SEMICONDUCTOR MEMORY DEVICE AND ELECTRONIC SYSTEM INCLUDING THE SAME

(71) Applicant: Samsung Electronics Co., Ltd., Suwon-si (KR)

(72) Inventor: Kang Lib KIM, Suwon-si (KR)

(21) Appl. No.: 19/292,729

(22) Filed: Aug. 6, 2025

(30) Foreign Application Priority Data
Dec. 24, 2024 (KR) 10-2024-0195847

(51) Int. Cl. H10B 43/27; H01L 23/00; H01L 25/065; H01L 25/18; H10B 43/10; H10B 43/35; H10B 80/00

(52) U.S. Cl. CPC H10B 43/27; H10B 43/10; H10B 43/35; H10B 80/00; H10W 90/00; H10W 90/792

(57) ABSTRACT

The semiconductor memory device comprises a substrate including a cell array region and an extension region adjacent to the cell array region, a stacked structure with stacked gate electrodes on the substrate, a channel structure on the cell array region and crossing the plurality of gate electrodes, a plurality of first gate contacts on the extension region; and a cutting pattern configured to the stacked structure. Each of the first gate contacts is connected to a corresponding gate electrode by passing through at least some of the plurality of gate electrodes. The cutting pattern includes a first extension portion and a bending portion. When viewed in a plan view, the extension region and the bending portion are arranged along the second direction, and the extension region is interposed between the cell region and the first extension portion in the third direction.

### CROSS-REFERENCE TO RELATED APPLICATION

This application claims priority from Korean Patent Application No. 10-2024-0195847 filed on Dec. 24, 2024 in the Korean Intellectual Property Office and all the benefits accruing therefrom under 35 U.S.C. 119, the contents of which in its entirety are herein incorporated by reference.

### BACKGROUND

As a semiconductor memory device capable of storing high-capacity data is used in an electronic system, increasing data storage capacity of a semiconductor memory device is desired. To increase data storage capacity of a semiconductor memory device, a semiconductor memory device including three-dimensionally arranged memory cells instead of two-dimensionally arranged memory cells has been proposed.

### SUMMARY

The present disclosure provides a semiconductor memory device with the improved degree of integration.

The present disclosure provides an electronic system including a semiconductor memory device with the improved degree of integration.

The present disclosure is not limited to those mentioned above and additional objects of the present disclosure, which are not mentioned herein, will be clearly understood by those skilled in the art from the following description of the present disclosure.

According to an aspect of the present disclosure, there is provided a semiconductor memory device comprising a substrate including a cell array region and an extension region adjacent to the cell array region, a stacked structure, which includes a plurality of gate electrodes stacked to be spaced apart from each other in a first direction crossing an upper surface of the substrate, on the substrate, a channel structure, which crosses the plurality of gate electrodes, on the cell array region, a plurality of first gate contacts, which correspond to the plurality of gate electrodes, on the extension region; and a cutting pattern cutting the stacked structure, wherein each of the first gate contacts is connected to a corresponding one of the plurality of gate electrodes by passing through at least some of the plurality of gate electrodes, the cutting pattern includes a first extension portion extended in a second direction crossing the first direction, and a bending portion extended from the first extension portion in a third direction crossing the first direction and the second direction, the extension region and the bending portion are arranged along the second direction when viewed in a plan view crossing the first direction, and the extension region is interposed between the cell region and the first extension portion in the third direction when viewed in a plan view crossing the first direction.

According to the aforementioned and other implementations of the present disclosure, there is provided a semiconductor memory device including a first cell block and a second cell block, which are adjacent to each other, the semiconductor memory device comprising a substrate, which includes a first cell array region and a first extension region inside the first cell block, and a second cell array region and a second extension region inside the second cell block, a stacked structure, which includes a plurality of gate electrodes stacked to be spaced apart from each other in a first direction crossing an upper surface of the substrate, on the substrate, a channel structure, which crosses the plurality of gate electrodes, on each of the first cell array region and the second cell array region, a plurality of gate contacts, which correspond to the plurality of gate electrodes, on the first extension region and the second extension region and a cutting pattern separating the stacked structure of the first cell block from the stacked structure of the second cell block, wherein each of the gate contacts is connected to a corresponding one of the plurality of gate electrodes by passing through at least some of the plurality of gate electrodes, the first cell array region and the second cell array region are extended in a second direction crossing the first direction, and are arranged in a third direction crossing the first direction and the second direction, the first extension region is interposed between the first cell array region and the second cell array region in the third direction, and the first extension region and the second extension region are arranged along the second direction.

According to the aforementioned and other implementations of the present disclosure, there is provided an electronic system comprising a main board, a semiconductor memory device, which includes a plurality of cell blocks, on the main board and a controller, which is electrically connected to the semiconductor memory device, on the main board, wherein the semiconductor memory device includes a substrate including a cell array region and an extension region inside the cell blocks, a stacked structure, which includes a plurality of gate electrodes stacked to be spaced apart from each other in a first direction crossing an upper surface of the substrate, a channel structure, which crosses the plurality of gate electrodes, on the cell array region, a plurality of gate contacts, which correspond to the plurality of gate electrodes, on the extension region and a cutting pattern cutting the stacked structure, each of the gate contacts is connected to a corresponding one of the plurality of gate electrodes by passing through at least some of the plurality of gate electrodes, a first length of the cell array region in a second direction crossing the first direction is greater than a second length of the extension region in the second direction, and in each of the cell blocks, the cell array region and the extension region are arranged along a third direction crossing the first and second directions.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail example implementations thereof with reference to the attached drawings, in which:

FIG. 1 is an example block diagram illustrating a semiconductor memory device according to some implementations.

FIG. 2 is an example circuit view illustrating a semiconductor memory device according to some implementations.

FIG. 3 is a layout view illustrating a semiconductor memory device according to some implementations.

FIG. 4 is an example enlarged view illustrating a region R1 of FIG. 3.

FIG. 5 is a schematic cross-sectional view taken along line A-A of FIG. 4.

FIG. 6 is an example enlarged view illustrating a region R2 of FIG. 5.

FIG. 7 is a schematic cross-sectional view taken along line A-A of FIG. 4.

FIG. 8 is a schematic partial layout view illustrating a gate contact and a conductive line of a semiconductor memory device according to some implementations.

FIG. 9 is another example enlarged view illustrating a region R1 of FIG. 3.

FIG. 10 is a schematic cross-sectional view taken along line C-C of FIG. 9.

FIG. 11 is a schematic cross-sectional view taken along line D-D of FIG. 9.

FIGS. 12a and 12b are various other example enlarged views illustrating a region R1 of FIG. 3.

FIGS. 13 to 15 are various layout views illustrating a semiconductor memory device according to some implementations.

FIG. 16 is an example block diagram illustrating an electronic system according to some implementations.

FIG. 17 is an example perspective view illustrating an electronic system according to some implementations.

FIG. 18 is a schematic cross-sectional view taken along line I-I of FIG. 17.

### DETAILED DESCRIPTION

Although terms such as first and second are used to describe various elements or components in the present specification, these elements or components are not limited by these terms. These terms are used to distinguish a single element or component from other elements or components. Therefore, a first element or component referred to below may be a second element or component within the technical idea of the present disclosure.

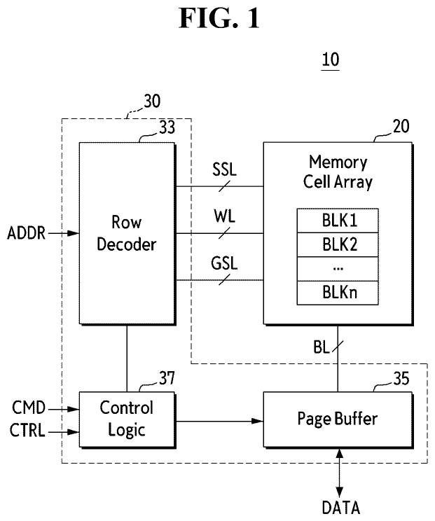

Hereinafter, a semiconductor memory device according to example implementations will be described with reference to FIGS. 1 to 11, 12a, 12b, and 13 to 15.

FIG. 1 is an example block diagram illustrating a semiconductor memory device according to some implementations.

A memory cell array 20 may include a plurality of memory cell blocks BLK1 to BLKn. Each of the memory cell blocks BLK1 to BLKn may include a plurality of memory cells. The memory cell array 20 may be connected to a peripheral circuit 30 through a bit line BL, a word line WL, at least one string selection line SSL and at least one ground selection line GSL. In detail, the memory cell blocks BLK1 to BLKn may be connected to a row decoder 33 through the word line WL, the string selection line SSL and the ground selection line GSL. In addition, the memory cell blocks BLK1 to BLKn may be connected to a page buffer 35 through the bit line BL.

The peripheral circuit 30 may receive an address ADDR, a command CMD and a control signal CTRL from the outside of the semiconductor memory device 10, and may transmit and receive data DATA to and from an external device of the semiconductor memory device 10. The peripheral circuit 30 may include a control logic 37, a row decoder 33 and a page buffer 35. The peripheral circuit 30 may further include various sub-circuits such as an input/output circuit, a voltage generating circuit for generating various voltages required for an operation of the semiconductor memory device 10 and an error correction circuit for correcting an error of the data DATA read from the memory cell array 20.

The control logic 37 may be connected to the row decoder 33, the input/output circuit and the voltage generating circuit. The control logic 37 may control the overall operation of the semiconductor memory device 10. The control logic 37 may generate various internal control signals used in the semiconductor memory device 10 in response to the control signal CTRL. For example, the control logic 37 may adjust a voltage level provided to the word line WL and the bit line BL when a memory operation such as a program operation or an erase operation is performed.

The row decoder 33 may select at least one of the plurality of memory cell blocks BLK1 to BLKn in response to the address ADDR, and may select at least one word line WL, at least one string selection line SSL and at least one ground selection line GSL of the selected memory cell blocks BLK1 to BLKn. In addition, the row decoder 33 may transfer a voltage for performing the memory operation to the word line WL of the selected memory cell blocks BLK1 to BLKn.

The page buffer 35 may be connected to the memory cell array 20 through the bit line BL. The page buffer 35 may operate as a write driver or a sense amplifier. In detail, when the program operation is performed, the page buffer 35 may operate as a write driver to apply a voltage according to the data DATA to be stored in the memory cell array 20, to the bit line BL. Meanwhile, when a read operation is performed, the page buffer 35 may operate as a sense amplifier to sense the data DATA stored in the memory cell array 20.

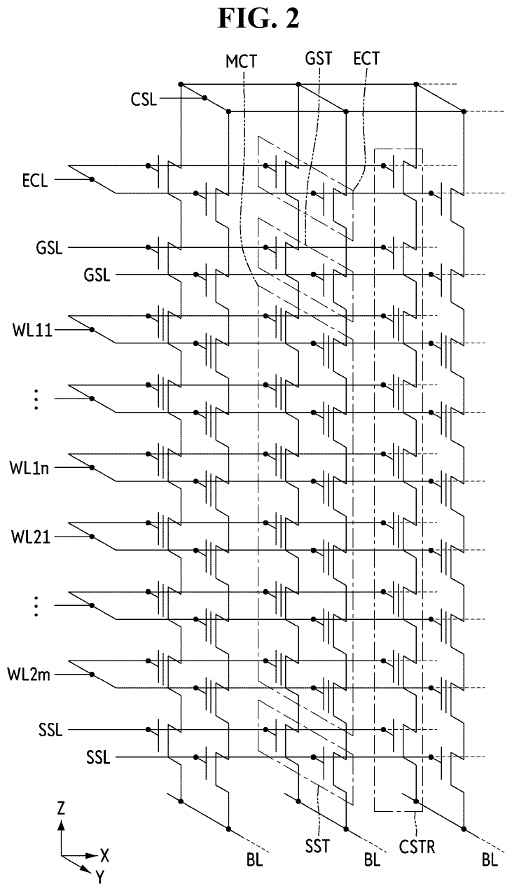

FIG. 2 is an example circuit view illustrating a semiconductor memory device according to some implementations.

Referring to FIG. 2, the memory cell array (e.g., 20 of FIG. 1) of the semiconductor memory device according to some implementations may include a plurality of cell strings CSTR.

The plurality of cell strings CSTR may be extended in a first direction Z, and may be arranged two-dimensionally on a plane (e.g., XY plane including a second direction X and a third direction Y) crossing the first direction Z.

The plurality of cell strings CSTR may be connected between a plurality of bit lines BL and a common source line CSL. The plurality of bit lines BL may be spaced apart from each other and arranged along the second direction X, or may be extended long in the third direction Y. The plurality of cell strings CSTR may be connected to the respective bit lines BL in parallel. The plurality of cell strings CSTR may be commonly connected to the common source line CSL.

Each of the cell strings CSTR may include a ground selection transistor GST connected to the common source line CSL, a string selection transistor SST connected to the bit line BL and a plurality of memory cell transistors MCT connected between the ground selection transistor GST and the string selection transistor SST. Each of the memory cell transistors MCT may include a data storage element. The ground selection transistor GST, the string selection transistor SST and the memory cell transistors MCT may be connected in series along the first direction Z.

The common source line CSL may be commonly connected to sources of the ground selection transistors GST. In addition, the ground selection line GSL, a plurality of word lines WL11 to WL1n and WL21 to WL2m and the string selection line SSL may be arranged between the common source line CSL and the bit line BL. The ground selection line GSL may be used as a gate electrode of the ground selection transistor GST, the word lines WL11 to WL1n and WL21 to WL2m may be used as gate electrodes of the memory cell transistors MCT, and the string selection line SSL may be used as a gate electrode of the string selection transistor SST.

In some implementations, an erase control transistor ECT may be arranged between the common source line CSL and the ground selection transistor GST. The common source line CSL may be commonly connected to sources of the erase control transistors ECT. An erase control line ECL may be arranged between the common source line CSL and the ground selection line GSL. The erase control line ECL may be used as a gate electrode of the erase control transistor ECT. The erase control transistor ECT may perform an erase operation of the memory cell array by using a gate induced drain leakage (GIDL).

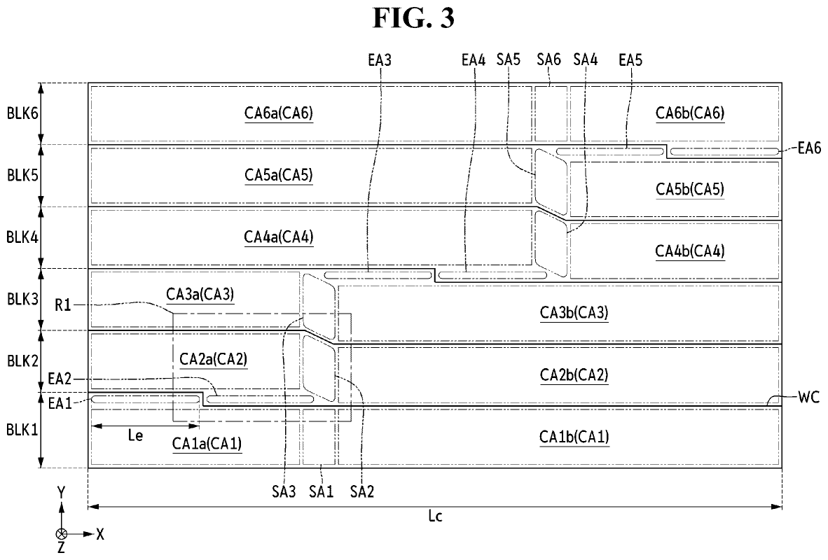

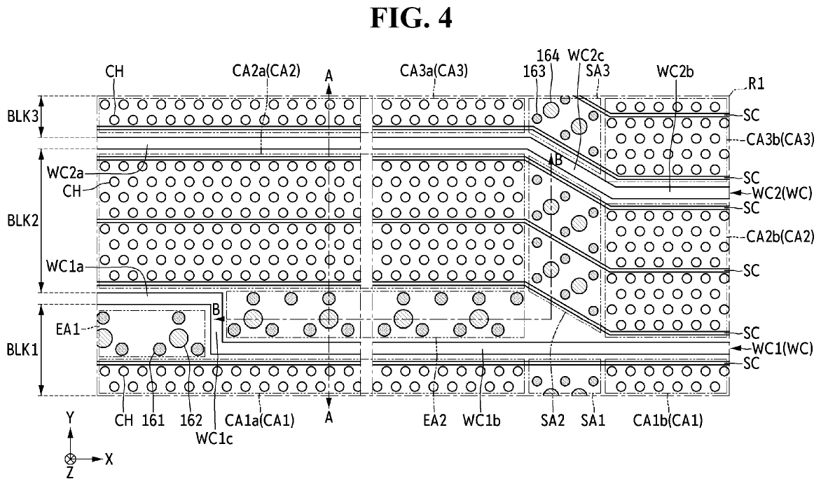

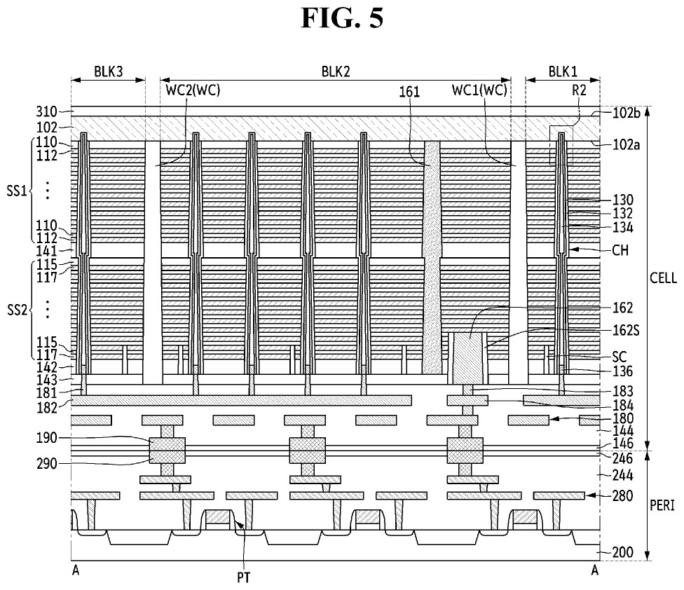

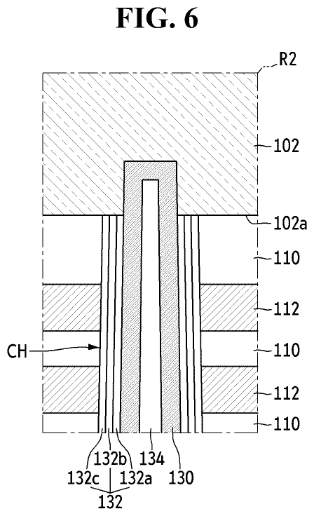

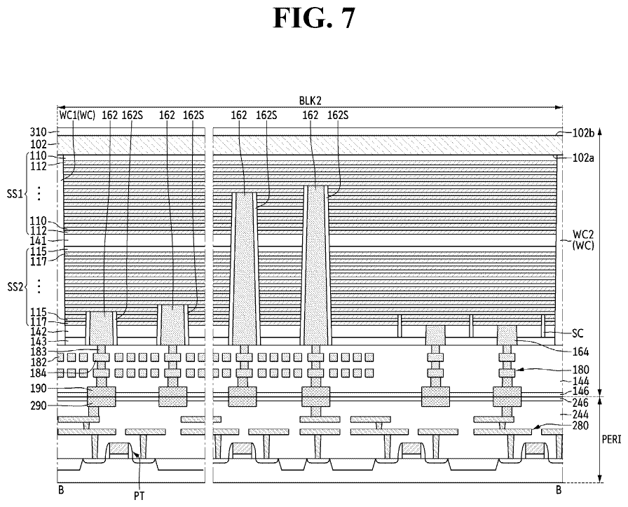

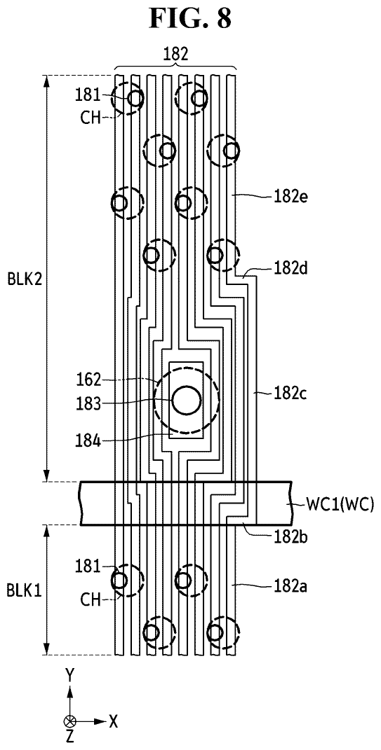

FIG. 3 is a layout view illustrating a semiconductor memory device according to some implementations. FIG. 4 is an example enlarged view illustrating a region R1 of FIG. 3. FIG. 5 is a schematic cross-sectional view taken along line A-A of FIG. 4. FIG. 6 is an example enlarged view illustrating a region R2 of FIG. 5. FIG. 6 is an enlarged view illustrating a region A of FIG. 4. FIG. 7 is a schematic cross-sectional view taken along line B-B of FIG. 4. FIG. 8 is a schematic partial layout view illustrating a gate contact and a conductive line of a semiconductor memory device according to some implementations.

Referring to FIGS. 1 to 8, the semiconductor memory device according to some implementations includes a memory cell structure CELL and a peripheral circuit structure PERI.

The memory cell structure CELL may include a plurality of memory cell blocks (e.g., BLK1 to BLKn of FIG. 1). For example, the memory cell structure CELL may include first to sixth cell blocks BLK1 to BLK6. The first to sixth cell blocks BLK1 to BLK6 may be sequentially arranged along the third direction Y. Each of the first to sixth cell blocks BLK1 to BLK6 may be extended long in the second direction X. A cutting pattern WC may be formed between the first to sixth cell blocks BLK1 to BLK6. The cutting pattern WC may be extended long in the second direction X to separate the first to sixth cell blocks BLK1 to BLK6 from each other.

The first to sixth cell blocks BLK1 to BLK6 may include first to sixth cell array regions CA1 to CA6 and first to sixth extension regions EA1 to EA6, respectively. A memory cell array (e.g., 20 of FIG. 1) including a plurality of memory cells may be formed in each of the first to sixth cell array regions CA1 to CA6. For example, a first substrate 102, gate electrodes 112 and 117, a channel structure CH and a conductive line 182, which will be described later, may be arranged in each of the first to sixth cell array regions CA1 to CA6. First gate contacts 162, which will be described later, may be arranged in each of the first to sixth extension regions EA1 to EA6.

The memory cell structure CELL may include a first substrate 102, a first stacked structure SS1, a first interlayer insulating film 141, a second stacked structure SS2, a channel structure CH, a cutting pattern WC, a string separation pattern SC, a first gate contact 162, a first insulating spacer 162S, a first support pattern 161, a first wiring structure 180, and a rear insulating film 310.

The first substrate 102 may include, for example, a semiconductor substrate such as a silicon substrate, a germanium substrate or a silicon-germanium substrate. Alternatively, the first substrate 102 may include a silicon-on-insulator (SOI) substrate or a germanium-on-insulator (GOI) substrate. In some implementations, the first substrate 102 may include polysilicon (poly Si).

The first substrate 102 may include a first surface 102a and a second surface 102b, which are opposite to each other. In the following description, the first surface 102a may be referred to as a front side, and the second surface 102b may be referred to as a rear side.

In some implementations, the first substrate 102 may include a conductive material, for example, polysilicon doped with impurities, metal or metal silicide. For example, the first substrate 102 may include polysilicon (poly-Si) doped with N-type impurities (e.g., phosphorus (P) or arsenic (As)). The first substrate 102 may be provided as a common source line (e.g., CSL of FIG. 2) of the semiconductor memory device according to some implementations.

The first stacked structure SS1 and the second stacked structure SS2 may be formed on the first substrate 102 of each of the first to sixth cell array regions CA1 to CA6 and the first substrate 102 of each of the first to sixth extension regions EA1 to EA6. The first stacked structure SS1 and the second stacked structure SS2 may be sequentially stacked on the first surface 102a of the first substrate 102.

The first stacked structure SS1 may include a plurality of first mold insulating films 110 and a plurality of first gate electrodes 112, which are alternately stacked along the first direction Z. Each of the first mold insulating films 110 and each of the first gate electrodes 112 may have a layered structure extended along a horizontal plane (e.g., XY plane). The first gate electrodes 112 may be stacked sequentially to be spaced apart from each other by the first mold insulating films 110.

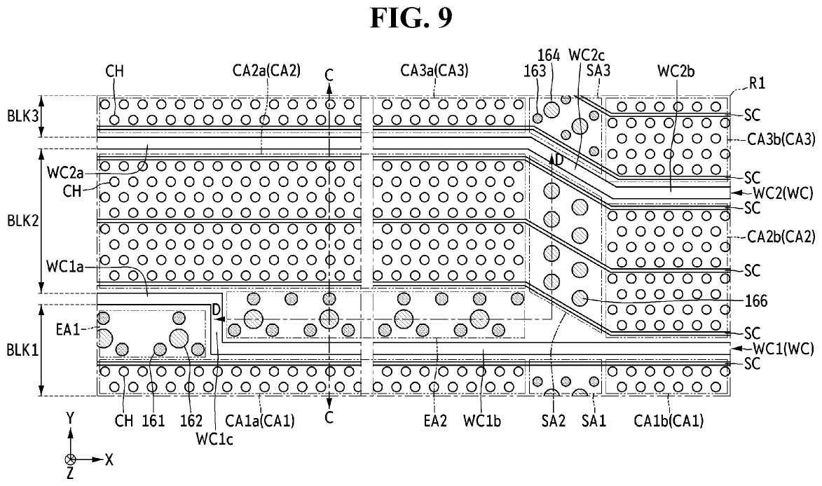

In some implementations, the first gate electrodes 112 may include at least one erase control line (e.g., ECL of FIG. 2), at least one ground selection line (e.g., GSL of FIG. 2) and a plurality of first word lines (e.g., WL11 to WL1n of FIG. 9), which are sequentially stacked on the first substrate 102. The number and thickness of the first mold insulating films 110 and the first gate electrodes 112 are examples and are not limited to the shown examples.

The first interlayer insulating film 141 may cover the first stacked structure SS1. The first interlayer insulating film 141 may include at least one of, for example, silicon oxide, silicon oxynitride and/or a low dielectric constant (low-k) material having a dielectric constant lower than that of silicon oxide, but is not limited thereto.

The second stacked structure SS2 may include a plurality of second mold insulating films 115 and a plurality of second gate electrodes 117, which are alternately stacked along the first direction Z. Each of the second mold insulating films 115 and each of the second gate electrodes 117 may have a layered structure in which they are extended along a horizontal plane (e.g., XY plane). The second gate electrodes 117 may be sequentially stacked to be spaced apart from each other by the second mold insulating films 115.

In some implementations, the second gate electrodes 117 may include a plurality of second word lines (e.g., WL21 to WL2m of FIG. 2) and at least one string selection line (e.g., SSL of FIG. 2), which are sequentially stacked on the first stacked structure SS1. The number and thickness of the second mold insulating films 115 and the second gate electrodes 117 are examples and are not limited to the shown examples.

The second interlayer insulating film 142 may cover the second stacked structure SS2. The second interlayer insulating film 142 may include at least one of, for example, silicon oxide, silicon oxynitride and/or a low dielectric constant (low-k) material having a dielectric constant lower than that of silicon oxide, but is not limited thereto.

Each of the gate electrodes 112 and 117 may include a conductive material, for example, metal such as tungsten (W), molybdenum (Mo), ruthenium (Ru), cobalt (Co) and nickel (Ni) or a semiconductor material such as silicon, but is not limited thereto. In some implementations, each of the gate electrodes 112 and 117 may include a metal film. For example, each of the gate electrodes 112 and 117 may include at least one of a tungsten (W) film, a molybdenum (Mo) film and/or a ruthenium (Ru) film.

Each of the mold insulating films 110 and 115 may include at least one of, for example, silicon oxide, silicon nitride and/or silicon oxynitride, but is not limited thereto. For example, each of the mold insulating films 110 and 115 may include a silicon oxide film.

The channel structure CH may be arranged on the first substrate 102 of the first to sixth cell array regions CA1 to CA6. The channel structure CH may be extended in the first direction Z to pass through at least a portion of the stacked structures SS1 and SS2. The channel structure CH may cross the plurality of gate electrodes 112 and 117. For example, the channel structure CH may be a pillar-shaped structure (e.g., a cylinder-shaped structure) extended in the first direction Z.

In some implementations, a plurality of channel structures CH may be arranged in a zigzag shape. For example, as shown in FIG. 4, the channel structures CH may be arranged to be alternate with each other in the second direction X and the third direction Y. The channel structures CH may further improve the degree of integration of the semiconductor memory device. The number and arrangement of the channel structures CH are examples and are not limited to the shown examples.

In some implementations, each of the channel structures CH may have a step difference between the first stacked structure SS1 and the second stacked structure SS2. For example, as shown in FIG. 5, sides of each of the channel structures CH may have a bending portion at a boundary between the first stacked structure SS1 and the second stacked structure SS2.

Each of the channel structures CH may include a semiconductor film 130 and a data storage film 132.

The semiconductor film 130 may be extended in the first direction Z to cross the plurality of gate electrodes 112 and 117. Although the semiconductor film 130 is shown as having a cup shape, this is an example. For example, the semiconductor film 130 may have various shapes such as a cylindrical shape, a quadrangular barrel shape and a filled pillar shape. The semiconductor film 130 may include, for example, a semiconductor material such as monocrystalline silicon, polycrystalline silicon, an organic semiconductor material and a carbon nanostructure, but is not limited thereto.

In some implementations, the semiconductor film 130 may be electrically connected to the first substrate 102. For example, one end (e.g., an upper end) of the semiconductor film 130 may be in contact with the first substrate 102.

In some implementations, the semiconductor film 130 may be more protruded than the first stacked structure SS1 and the data storage film 132. For example, one end (e.g., an upper end) of the semiconductor film 130 may be formed to be higher than an upper surface of the first stacked structure SS1 and an upper surface of the data storage film 132. The first substrate 102 may be in contact with one end (e.g., the upper end) of the semiconductor film 130 that is more protruded than the first stacked structure SS1 and the data storage film 132.

The data storage film 132 may be interposed between the semiconductor film 130 and the plurality of gate electrodes 112 and 117. For example, the data storage film 132 may be extended along an outer side of the semiconductor film 130. For example, the data storage film 132 may include at least one of silicon oxide, silicon nitride, silicon oxynitride or a high dielectric constant material having a dielectric constant higher than that of silicon oxide, but is not limited thereto. The high dielectric constant material may include, for example, at least one of aluminum oxide, hafnium oxide, lanthanum oxide, tantalum oxide, titanium oxide, lanthanum hafnium oxide, lanthanum aluminum oxide, dysprosium scandium oxide or their combination.

In some implementations, as shown in FIG. 6, the data storage film 132 may include a tunnel insulating film 132a, a charge storage film 132b and a blocking insulating film 132c, which are sequentially stacked on the outer side of the semiconductor film 130.

The tunnel insulating film 132a may include, for example, silicon oxide or a high dielectric constant material (e.g., aluminum oxide (Al₂O₃) or hafnium oxide (HfO₂)) having a dielectric constant higher than that of silicon oxide. The charge storage film 132b may include, for example, silicon nitride. The blocking insulating film 132c may include, for example, silicon oxide or a high dielectric constant material (e.g., aluminum oxide (Al₂O₃) or hafnium oxide (HfO₂)) having a dielectric constant higher than that of silicon oxide.

In some implementations, the channel structure CH may further include a filling insulating film 134. The filling insulating film 134 may be formed to fill the inside of the cup-shaped semiconductor film 130. The filling insulating film 134 may include at least one of silicon oxide, silicon nitride and/or silicon oxynitride, but is not limited thereto.

In some implementations, the channel structure CH may further include a channel pad 136. The channel pad 136 may be electrically connected to the other end (e.g., a lower end) of the semiconductor film 130. The channel pad 136 may include a conductive material, for example, polysilicon doped with impurities, metal or metal silicide. For example, the channel pad 136 may include polysilicon (poly-Si) doped with N-type impurities (e.g., phosphorus (P) or arsenic (As)).

The cutting pattern WC may cut the stacked structures SS1 and SS2. For example, as shown in FIG. 5, an uppermost surface of the cutting pattern WC may be formed to be equal to or higher than the upper surface of the first stacked structure SS1, and a lowermost surface of the cutting pattern WC may be formed to be equal to or lower than a lower surface of the second stacked structure SS2.

Each of a plurality of cutting patterns WC may be extended long in the second direction X, and may be spaced apart from each other and arranged along the third direction Y. The stacked structures SS1 and SS2 may be divided by the plurality of cutting patterns WC to form a plurality of memory cell blocks (e.g., BLK1 to BLKn of FIG. 1). For example, as shown in FIG. 4, the cutting patterns may include a first cutting pattern WC1 and a second cutting pattern WC2. The first cutting pattern WC1 may separate the first cell block BLK1 from the second cell block BLK2. The second cutting pattern WC2 may separate the second cell block BLK2 from the third cell block BLK3.

In some implementations, the cutting pattern WC may include an insulating material, for example, at least one of silicon oxide, silicon nitride and/or silicon oxynitride. For example, the cutting pattern WC may include a silicon oxide film.

The string separation pattern SC may be formed in the stacked structures SS1 and SS2. The string separation pattern SC may be extended long in the second direction X to cut a string selection line (SSL of FIG. 2; e.g., a gate electrode, which is arranged at a lowermost portion, among the second gate electrodes 117). Each of the memory cell blocks (e.g., BLK1 to BLKn of FIG. 1) defined by the cutting patterns WC may be divided by the string separation pattern SC to form a plurality of string regions. For example, as shown in FIG. 4, the string separation pattern SC may define two string regions in the second cell block BLK2.

The string separation pattern SC may include an insulating material, for example, at least one of silicon oxide, silicon nitride, and/or silicon oxynitride. For example, the string separation pattern SC may include a silicon nitride film.

The first gate contact 162 may be formed on the first substrate 102 of each of the first to sixth extension regions EA1 to EA6. A plurality of first gate contacts 162 may be connected to the plurality of gate electrodes 112 and 117 corresponding thereto. For example, each of the first gate contacts 162 may be extended in the first direction Z and connected to a corresponding one of the gate electrodes 112 and 117. In some implementations, each of the first gate contacts 162 may be connected to one of the first word lines (e.g., WL11 to WL1n of FIG. 2) or one of the second word lines (e.g., WL21 to WL2m of FIG. 2).

In some implementations, each of the first gate contacts 162 may be connected to a corresponding one (hereinafter, referred to as a selection gate electrode) of the gate electrodes 112 and 117 by passing through at least some (hereinafter, referred to as non-selection gate electrodes) of the gate electrodes 112 and 117.

The first insulating spacer 162S may surround a side of each of the first gate contacts 162. For example, the first insulating spacer 162S may be extended to be conformal along the side of each of the first gate contacts 162. The first insulating spacer 162S may include at least one of, for example, silicon oxide, silicon nitride, and/or silicon oxynitride, but is not limited thereto. The first insulating spacer 162S may physically and electrically separate the first gate contacts 162 from the non-selection gate electrodes.

In some implementations, each of the first gate contacts 162 may pass through the second interlayer insulating film 142. For example, a third interlayer insulating film 143 may be formed on the second interlayer insulating film 142. Each of the first gate contacts 162 may be connected to the selection gate electrode by passing through the third interlayer insulating film 143, the second interlayer insulating film 142 and the non-selection gate electrodes.

In some implementations, a width of each of the first gate contacts 162 may be reduced in a direction toward the first substrate 102. This may be due to an etching process for forming the first gate contacts 162, which is performed in a direction from the stacked structures SS1 and SS2 toward the first substrate 102.

The first support pattern 161 may be formed on the first substrate 102 of each of the first to sixth extension regions EA1 to EA6. The first support pattern 161 may be extended in the first direction Z and pass through at least a portion of the stacked structures SS1 and SS2. The first support pattern 161 may cross the plurality of gate electrodes 112 and 117. For example, the first support pattern 161 may be a pillar-shaped (e.g., cylindrical) structure extended in the first direction Z.

A plurality of first support patterns 161 may be formed around the first gate contacts 162, respectively. The first supporting pattern 161 may prevent the stacked structures SS1 and SS2 from collapsing or falling by supporting the mold insulating films 110 and 115 of the first to sixth extension regions EA1 to EA6 in a replacement process for forming the gate electrodes 112 and 117. The number and arrangement of the first supporting patterns 161 are examples and are not limited to the shown examples.

In some implementations, each of the first support patterns 161 may have a step difference between the first stacked structure SS1 and the second stacked structure SS2. For example, as shown in FIG. 5, each side of the first support patterns 161 may have a bending portion at a boundary between the first stacked structure SS1 and the second stacked structure SS2.

The first support pattern 161 may be formed at the same level as the channel structure CH, or may be formed at a different level from the channel structure CH. In some implementations, the first support pattern 161 may include an insulating material, for example, at least one of silicon oxide, silicon nitride, and/or silicon oxynitride.

The first wiring structure 180 may be formed on the third interlayer insulating film 143. The first wiring structure 180 may provide an electrical path for an operation of each memory cell. For example, the first inter-wiring insulating film 144 may be formed on the third interlayer insulating film 143. The first wiring structure 180 may be formed in the first inter-wiring insulating film 144 and connected to the first substrate 102, the channel structure CH and/or the first gate contact 162. The number of layers and arrangement of the first wiring structure 180 are examples and are not limited to the shown examples.

The first wiring structure 180 may include a conductive material, for example, at least one of aluminum (Al), copper (Cu), tungsten (W), molybdenum (Mo), cobalt (Co), ruthenium (Ru), or their combination, but is not limited thereto. For example, the first wiring structure 180 may include a copper (Cu) wiring.

In some implementations, the first wiring structure 180 may include conductive lines 182 arranged on the stacked structures SS1 and SS2 of each of the first to sixth cell array regions CA1 to CA6. The conductive lines 182 may be extended long in the third direction Y. Also, the plurality of conductive lines 182 may be extended in the third direction Y, and may be spaced apart from each other and arranged along the second direction X.

The conductive line 182 may be electrically connected to a plurality of channel structures CH arranged along the third direction Y. For example, a first contact pattern 181 connecting the channel pad 136 to the conductive line 182 may be formed. The conductive line 182 may be connected to the other end (e.g., the lower end) of the semiconductor film 130 through the first contact pattern 181. The conductive line 182 may be provided as a bit line (e.g., BL of FIG. 2) of the semiconductor memory device according to some implementations.

In some implementations, the first wiring structure 180 may include a first connection pattern 184 arranged on the stacked structures SS1 and SS2 of each of the first to sixth extension regions EA1 to EA6. The first connection pattern 184 may be physically and electrically separated from the conductive line 182.

The first connection pattern 184 may be electrically connected to each of the first gate contacts 162. For example, a second contact pattern 183 connecting each of the first gate contacts 162 to the first connection pattern 184 may be formed. The first connection pattern 184 may be connected to each of the first gate contacts 162 through the second contact pattern 183.

In some implementations, each of the conductive lines 182 may be electrically connected to the plurality of channel structures CH arranged along the third direction Y through the plurality of memory cell blocks (e.g., BLK1 to BLKn of FIG. 1). For example, as shown in FIG. 8, each of the conductive lines 182 may connect the channel structure CH of the first cell block BLK1 to the channel structure CH of the second cell block BLK2.

In some implementations, as shown in FIG. 8, some of the plurality of conductive lines 182 may connect the channel structure CH of the first cell block BLK1 to the channel structure CH of the second cell block BLK2 by avoiding the first connection pattern 184. For example, a conductive line 182 including first to fifth portions 182a to 182e may be provided. The first portion 182a may be extended long in the third direction Y. The first portion 182a may be connected to the channel structure CH of the first cell block BLK1. The second portion 182b may be bent from one end of the first portion 182a and extended in the second direction X. The third portion 182c may be bent from one end of the second portion 182b and extended long in the third direction Y. The third portion 182c may overlap the first connection pattern 184 in the second direction X. The fourth portion 182d may be bent from one end of the third portion 182c and extended in the second direction X. The fifth portion 182e may be bent from one end of the fourth portion 182d and extended in the third direction Y. The fifth portion 182e may be connected to the channel structure CH of the second cell block BLK2.

The rear insulating film 310 may be formed on the second surface 102b of the first substrate 102. The rear insulating film 310 may include at least one of, for example, silicon oxide, silicon oxynitride and/or a low dielectric constant (low-k) material having a dielectric constant lower than that of silicon oxide, but is not limited thereto.

The peripheral circuit structure PERI may include a second substrate 200, a peripheral circuit element PT, and a second wiring structure 280.

The second substrate 200 may include, for example, a semiconductor substrate such as a silicon substrate, a germanium substrate or a silicon-germanium substrate. Alternatively, the second substrate 200 may include a silicon-on-insulator (SOI) substrate or a germanium-on-insulator (GOI) substrate.

The peripheral circuit element PT may be formed on the second substrate 200. The peripheral circuit element PT may constitute a peripheral circuit (e.g., 30 of FIG. 1) that controls the operation of the semiconductor memory device. For example, the peripheral circuit element PT may include a control logic (e.g., 37 of FIG. 1), a row decoder (e.g., 33 of FIG. 1), a page buffer (e.g., 35 of FIG. 1), and the like.

The peripheral circuit element PT may include, for example, a transistor, but is not limited thereto. For example, the peripheral circuit element PT may include various passive elements such as a capacitor, a resistor and an inductor as well as various active elements such as a transistor.

The second wiring structure 280 may be formed on the peripheral circuit element PT. For example, a second inter-wiring insulating film 244 may be formed on the entire surface of the second substrate 200. The second wiring structure 280 may be formed in the second inter-wiring insulating film 244 and electrically connected to the peripheral circuit element PT. The number of layers and arrangement of the second wiring structure 280 are exemplarily shown, and are not limited thereto.

In some implementations, the memory cell structure CELL may be stacked on the peripheral circuit structure PERI. For example, the memory cell structure CELL and the peripheral circuit structure PERI may be arranged along the first direction Z.

In some implementations, the first surface 102a of the first substrate 102 may face the peripheral circuit structure PERI.

The semiconductor memory device according to some implementations may have a chip to chip (C2C) structure. The C2C structure means that an upper chip including a memory cell structure CELL is manufactured on a first wafer and a lower chip including a peripheral circuit structure PERI is manufactured on a second wafer different from the first wafer, and then the upper chip and the lower chip are connected to each other by a bonding method.

For example, the bonding method may mean a method for electrically connecting a first bonding metal 190 (and/or a first bonding insulating film 146) formed on the uppermost metal layer of the upper chip with a second bonding metal 290 (and/or a second bonding insulating film 246) formed on the uppermost metal layer of the lower chip. For example, when the first bonding metal 190 and the second bonding metal 290 are formed of copper (Cu), the bonding method may be a Cu-Cu bonding method. However, this is an example, and the first bonding metal 190 and the second bonding metal 290 may be formed of various other metals such as aluminum (Al) or tungsten (W).

As the first bonding metal 190 and the second bonding metal 290 are bonded to each other, the first wiring structure 180 may be electrically connected to the second wiring structure 280. Therefore, the plurality of memory cells of the memory cell structure CELL may be electrically connected to the peripheral circuit element PT.

Referring back to FIGS. 3 and 4, in each of the first to sixth cell blocks BLK1 to BLK6, the first to sixth extension regions EA1 to EA6 may be arranged along the third direction Y together with the first to sixth cell array regions CA1 to CA6, respectively. For example, as shown in FIG. 4, the first cell array region CA1 and the first extension region EA1 may be arranged along the third direction Y, and the second cell array region CA2 and the second extension region EA2 may be arranged along the third direction Y.

The plurality of first gate contacts 162 may be arranged long in the second direction X in each of the first to sixth extension regions EA1 to EA6. For example, as shown in FIG. 4, the first gate contacts 162 of the second cell block BLK2 may be arranged in a line along the second direction X in the second extension region EA2.

In the second direction X, a length of each of the first to sixth cell array regions CA1 to CA6 may be greater than a length of each of the first to sixth extension regions EA1 to EA6. For example, as shown in FIG. 3, a first length Lc of the first cell array region CA1 in the second direction X may be greater than a second length Le of the first extension region EA1 in the second direction X. In some implementations, the first length Lc may be twice or more of the second length Le.

In some implementations, when the memory cell structure CELL includes ‘n’ (where ‘n’ is a natural number of 2 or more) number of memory cell blocks (e.g., BLK1 to BLKn of FIG. 1), the length of each of the first to sixth cell array regions CA1 to CA6 may be ‘n’ times or more of the length of each of the first to sixth extension regions EA1 to EA6, and may be (n+1) times or less of the length of each of the first to sixth extension regions EA1 to EA6. For example, when the memory cell structure CELL includes first to sixth cell blocks BLK1 to BLK6, as shown in FIG. 3, the first length Lc may be six times or more of the second length Le and seven times or less of the second length Le.

In some implementations, some of the first to sixth extension regions EA1 to EA6 may be arranged along the second direction X. For example, the first extension region EA1 and the second extension region EA2 may be arranged along the second direction X, the third extension region EA3 and the fourth extension region EA4 may be arranged along the second direction X, or the fifth extension region EA5 and the sixth extension region EA6 may be arranged along the second direction X.

In some implementations, the third extension region EA3 and the fourth extension region EA4 may not overlap the first extension region EA1 and the second extension region EA2 in the third direction Y. In some implementations, the fifth extension region EA5 and the sixth extension region EA6 may not overlap the first extension region EA1, the second extension region EA2, the third extension region EA3 and the fourth extension region EA4 in the third direction Y.

In some implementations, the cutting pattern WC may separate the first extension region EA1 from the second extension region EA2 in the second direction X. For example, as shown in FIG. 4, the first cutting pattern WC1 may include a first extension portion WC1a, a second extension portion WC1b, and a first bending portion WC1c. The first extension portion WC1a may be extended long in the second direction X between the first extension region EA1 and the second cell array region CA2. The second extension portion WC1b may be extended long in the second direction X between the first cell array region CA1 and the second extension region EA2. The first bending portion WC1c may connect the first extension portion WC1a with the second extension portion WC1b between the first extension region EA1 and the second extension region EA2. For example, the first bending portion WC1c may be extended in the third direction Y.

In some implementations, the second to fifth cell array regions CA2 to CA5 may have a bent shape corresponding to the arrangement of the first to sixth extension regions EA1 to EA6. For example, the first to sixth cell array regions CA1 to CA6 may include first sub cell array regions CA1a to CA6a and second sub cell array regions CA1b to CA6b, respectively, which are arranged along the second direction X. In this case, based on the first sub cell array regions CA2a to CA5a of the second to fifth cell array regions CA2 to CA5, the second sub cell array regions CA2b to CA5b of the second to fifth cell array regions CA2 to CA5 may be shifted in the third direction Y. For example, as shown, a portion of the first sub cell array region CA2a of the second cell array region CA2 may not overlap the second sub cell array region CA2b of the second cell array region CA2 in the second direction X, and a portion of the second sub cell array region CA2b of the second cell array region CA2 may not overlap the first sub cell array region CA2a of the second cell array region CA2 in the second direction X. The shifted form of the second sub-cell array regions CA2b to CA5b of the second to fifth cell array regions CA2 to CA5 may correspond to the arrangement of the first to sixth extension regions EA1 to EA6. For example, as shown, one end of the second extension region EA2 may be positioned between the first sub-cell array region CA2a of the second cell array region CA2 and the second sub-cell array region CA2b of the second cell array region CA2.

In some implementations, the first to sixth cell blocks BLK1 to BLK6 may further include first to sixth space regions SA1 to SA6, respectively. The first to sixth space regions SA1 to SA6 may be formed in the first to sixth cell array regions CA1 to CA6, respectively. For example, the first to sixth space regions SA1 to SA6 may be interposed between the first sub cell array regions CA1a to CA6a and the second sub cell array regions CA1b to CA6b in the second direction X.

In some implementations, the first to third space regions SA1 to SA3 may be arranged along the third direction Y. In some implementations, the fourth to sixth space regions SA4 to SA6 may be arranged along the third direction Y.

In some implementations, at least one second gate contact 164 may be formed on the first substrate 102 of at least some of the first to sixth space regions SA1 to SA6. The second gate contact 164 may be connected to each string region divided by the string separation pattern SC. For example, the second gate contact 164 may be connected to a string selection line (e.g., SSL of FIG. 2). Alternatively, for example, the second gate contact 164 may be connected to an erase control line (e.g., ECL of FIG. 2).

As the second gate contact 164 is arranged on the first to sixth space regions SA1 to SA6, the second gate contact 164 may control both the first sub-cell array regions CA1a to CA6a and the second sub-cell array regions CA1b to CA6b, which are arranged on both sides of the second gate contact 164. For example, the second gate contact 164 arranged on the second space region SA2 may be commonly connected to the string region of the first sub-cell array region CA2a of the second cell array region CA2 and the string region of the second sub-cell array region CA2b of the second cell array region CA2. The second gate contact 164 may further improve the degree of integration of the semiconductor memory device in the second direction X.

In some implementations, a second support pattern 163 may be formed on the first substrate 102 of each of the first to sixth space regions SA1 to SA6. The second support pattern 163 may be extended in the first direction Z to pass through at least a portion of the stacked structures SS1 and SS2. The second support pattern 163 may cross the plurality of gate electrodes 112 and 117. For example, the second support pattern 163 may be a pillar-shaped (e.g., cylindrical) structure extended in the first direction Z.

A plurality of second support patterns 163 may be formed around the second gate contact 164. The second support pattern 163 may prevent the stacked structures SS1 and SS2 from collapsing or falling by supporting the mold insulating films 110 and 115 of the first to sixth space regions SA1 to SA6 in a replacement process for forming the gate electrodes 112 and 117. The number and arrangement of the second support patterns 163 are examples and are not limited to the shown examples.

The second support pattern 163 may be formed at the same level as the first support pattern 161, or may be formed at a different level from the first support pattern 161. In some implementations, the second support pattern 163 may include an insulating material, for example, at least one of silicon oxide, silicon nitride, and/or silicon oxynitride.

In some implementations, the cutting pattern WC may separate the second space region SA2 from the third space region SA3 in the third direction Y. For example, as shown in FIG. 4, the second cutting pattern WC2 may include a third extension portion WC2a, a fourth extension portion WC2b, and a second bending portion WC2c. The third extension portion WC2a may be extended long in the second direction X between the first sub-cell array region CA2a of the second cell array region CA2 and the first sub-cell array region CA3a of the third cell array region CA3. The fourth extension portion WC2b may be extended long in the second direction X between the second sub-cell array region CA2b of the second cell array region CA2 and the second sub-cell array region CA3b of the third cell array region CA3. The second bending portion WC2c may connect the third extension portion WC2a with the fourth extension portion WC2b between the third space region SA3 and the second space region SA2. For example, the second bending portion WC2c may be extended in a diagonal direction between the first direction Z and the second direction X.

In the semiconductor memory device including three-dimensionally arranged memory cells, a non-stepwise structure in which gate contacts are formed on gate electrodes that are not stacked in a stepwise manner has been proposed. In the non-stepwise structure, the gate contacts may be connected to the selection gate electrode by passing through some of the non-selection gate electrodes. As the number of stacked memory cells continues to increase, an area of the extension region in which the gate contacts are arranged is also increasing. Accordingly, methods for improving the degree of integration by reducing an area of an extension region are being studied.

In the semiconductor memory device according to some implementations, the memory cell blocks (e.g., the first to sixth cell blocks BLK1 to BLK6) may provide extension regions (the first to sixth extension regions EA1 to EA6), respectively, each of which has a reduced area. In detail, as described above, the first gate contacts 162 may be arranged one-dimensionally (e.g., in a line) along the second direction X, respectively, in each of the first to sixth extension regions EA1 to EA6. The arrangement of the first gate contacts 162 may reduce an occupied area in the third direction Y as compared with the gate contacts arranged two-dimensionally. In addition, as described above, some of the first to sixth extension regions EA1 to EA6 may be arranged along the second direction X, and the second to fifth cell array regions CA2 to CA5 may have a bent shape corresponding to the arrangement of the first to sixth extension regions EA1 to EA6. Accordingly, a semiconductor memory device with the degree of integration improved by increased utilization of space may be provided.

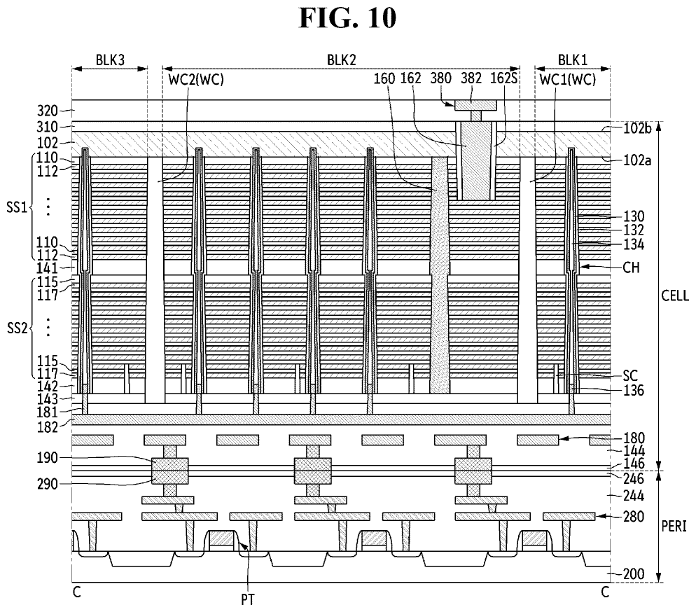

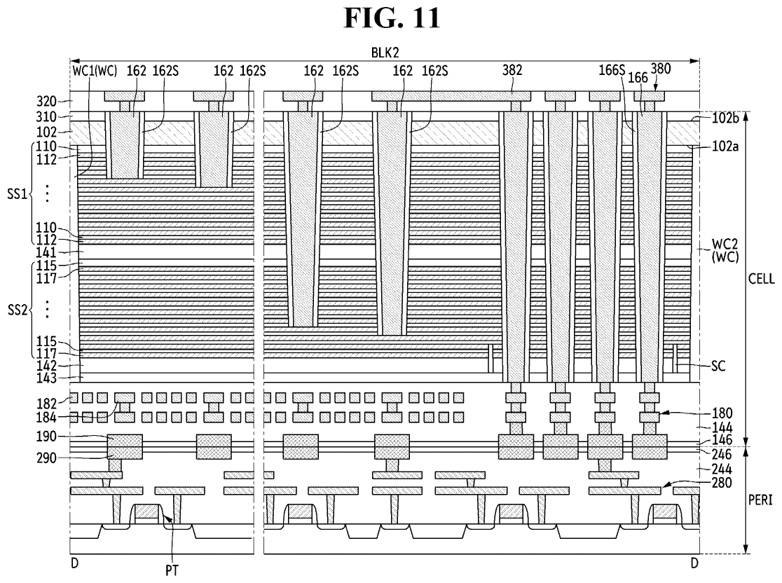

FIG. 9 is another example enlarged view illustrating a region R1 of FIG. 3. FIG. 10 is a schematic cross-sectional view taken along line C-C of FIG. 9. FIG. 11 is a schematic cross-sectional view taken along line D-D of FIG. 9. For convenience of description, redundant portions of those described above with reference to FIGS. 1 to 8 will be briefly described or omitted.

Referring to FIGS. 3 and 9 to 11, in the semiconductor memory device according to some implementations, each of the first gate contacts 162 may pass through the first substrate 102.

For example, each of the first gate contacts 162 may be connected to the selection gate electrode by passing through the rear insulating film 310, the first substrate 102 and the non-selection gate electrodes.

In some implementations, a width of each of the first gate contacts 162 may be reduced in a direction toward the first wiring structure 180. This may be due to an etching process for forming the first gate contacts 162, which is performed in a direction from the first substrate 102 toward the stacked structures SS1 and SS2.

In some implementations, a third inter-wiring insulating film 320 and a third wiring structure 380 may be formed on the rear insulating film 310. The third wiring structure 380 may be formed in the third inter-wiring insulating film 320 and connected to the first substrate 102 and/or the first gate contact 162. The number of layers and arrangement of the third wiring structure 380 are examples and are not limited to the shown examples.

In some implementations, at least one through contact 166 may be formed on the first substrate 102 of at least some of the first to sixth space regions SA1 to SA6. The through contact 166 may be extended in the first direction Z to pass through the first substrate 102 and the stacked structures SS1 and SS2. The through contact 166 may electrically connect the first gate contact 162 with the peripheral circuit structure PERI. For example, the third wiring structure 380 may include a second connection pattern 382 connecting the first gate contact 162 to the through contact 166. Accordingly, the plurality of memory cells of the memory cell structure CELL may be electrically connected to the peripheral circuit element PT.

In some implementations, a second insulating spacer 166S surrounding a side of the through contact 166 may be formed. For example, the second insulating spacer 166S may be extended to be conformal along the side of the through contact 166. The second insulating spacer 166S may include at least one of, for example, silicon oxide, silicon nitride, and/or silicon oxynitride, but is not limited thereto. The second insulating spacer 166S may physically and electrically separate the through contact 166 from the gate electrodes 112 and 117.

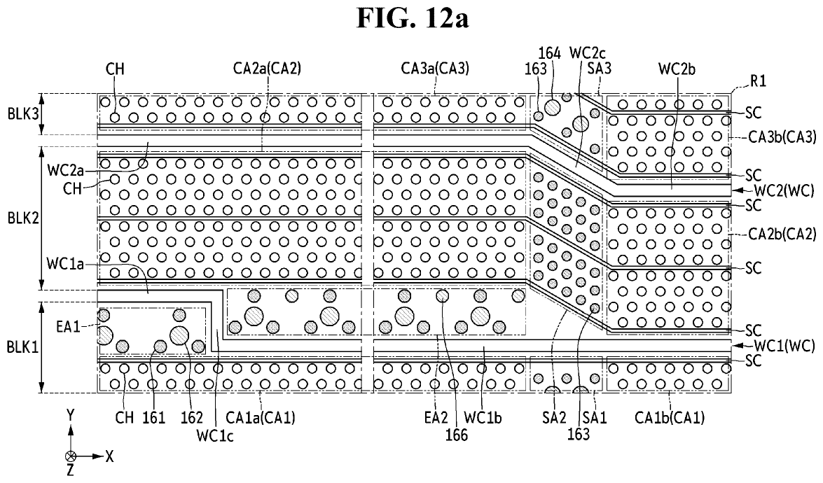

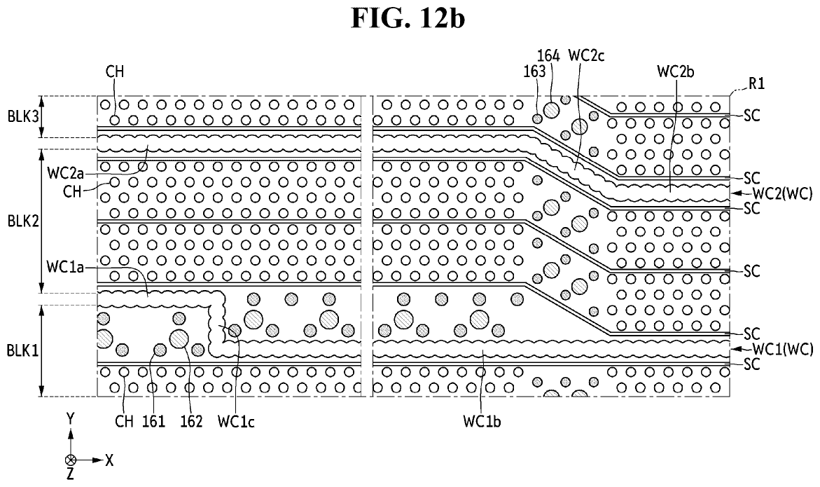

FIGS. 12a and 12b are various other example enlarged views illustrating a region R1 of FIG. 3. For convenience of description, redundant portions of those described above with reference to FIGS. 1 to 11 will be briefly described or omitted.

Referring to FIGS. 3 and 12a, in the semiconductor memory device according to some implementations, at least one through contact 166 may be formed on the first substrate 102 of at least some of the first to sixth extension regions EA1 to EA6.

For example, a plurality of through contacts 166 corresponding to a plurality of first gate contacts 162 may be formed on the first extension region EA1. The through contact 166 may electrically connect the first gate contact 162 with the peripheral circuit structure PERI. For example, in the description of FIGS. 10 and 11, the above-described second connection pattern 382 may connect the first gate contact 162 with the through contact 166 on the first extension region EA1.

Referring to FIGS. 3 and 12b, in the semiconductor memory device according to some implementations, a side of the cutting pattern WC may include a plurality of curved surfaces.

In detail, when viewed in a plan view crossing the first direction Z, the side of the cutting pattern WC may be formed by connecting a plurality of convex surfaces to each other. For example, a side of a first extension portion WC1a may be formed by connecting convex surfaces convex in the third direction Y to each other along the second direction X. Alternatively, for example, the side of the first bending portion WC1c may be formed by connecting convex surfaces convex in the second direction X to each other along the third direction Y.

In some implementations, the cutting pattern WC may be formed by connecting a plurality of cylindrical structures respectively extended in the first direction Z to each other. For example, a plurality of circular through holes respectively extended in the first direction Z to pass through the stacked structures SS1 and SS2 and connected to each other may be formed. The cutting pattern WC may be formed by filling an insulating material in the plurality of circular through holes.

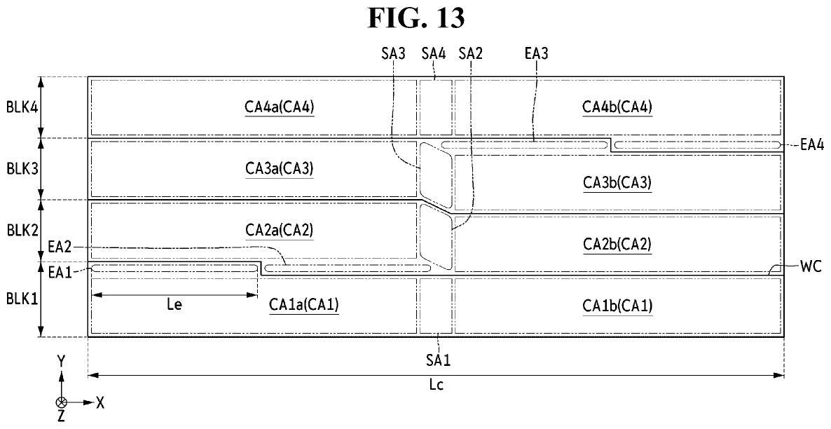

FIGS. 13 to 15 are various layout views illustrating a semiconductor memory device according to some implementations. For convenience of description, redundant portions of those described above with reference to FIGS. 1 to 11, 12a, and 12b will be briefly described or omitted.

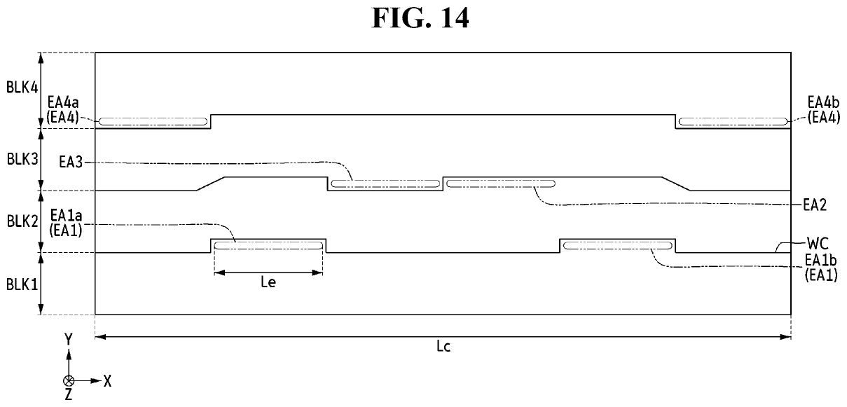

Referring to FIGS. 13 and 14, the semiconductor memory device according to some implementations may include first to fourth cell blocks BLK1 to BLK4.

A first length Lc may be four times or more of the second length Le and five times or less of the second length Le. The first extension region EA1 and the second extension region EA2 may be arranged along the second direction X, and the third extension region EA3 and the fourth extension region EA4 may be arranged along the second direction X. In some implementations, the third extension region EA3 and the fourth extension region EA4 may not overlap the first extension region EA1 and the second extension region EA2 in the third direction Y.

In some implementations, the second and third cell array regions CA2 and CA3 may have a bent shape corresponding to the arrangement of the first to fourth extension regions EA1 to EA4. For example, as shown, a portion of the first sub-cell array region CA2a of the second cell array region CA2 may not overlap the second sub-cell array region CA2b of the second cell array region CA2 in the second direction X, and a portion of the second sub-cell array region CA2b of the second cell array region CA2 may not overlap the first sub-cell array region CA2a of the second cell array region CA2 in the second direction X. For example, as shown, one end of the second extension region EA2 may be positioned between the first sub-cell array region CA2a of the second cell array region CA2 and the first sub-cell array region CA1a of the first cell array region CA1.

In some implementations, the first to fourth space regions SA1 to SA4 may be arranged along the third direction Y.

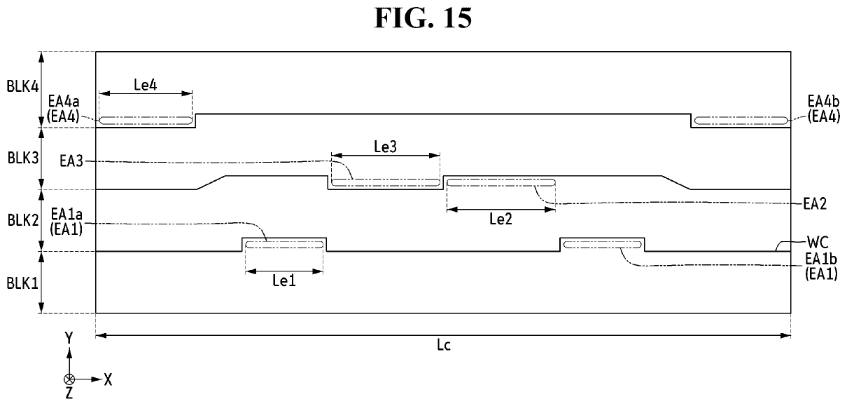

Referring to FIGS. 14 and 15, in the semiconductor memory device according to some implementations, at least a portion of the first to fourth cell blocks BLK1 to BLK4 may include a plurality of extension regions.

For example, the first extension region EA1 may include a first sub-extension region EA1a and a second sub-extension region EA1b. The first sub-extension region EA1a and the second sub-extension region EA1b may be spaced apart from each other in the second direction X. For example, the fourth extension region EA4 may include a third sub-extension region EA4a and a fourth sub-extension region EA4b. The third sub-extension region EA4a and the fourth sub-extension region EA4b may be spaced apart from each other in the second direction X.

The first cell block BLK1 and the fourth cell block BLK4 may prevent signal delay caused by bias of the extension region from occurring. For example, as shown in FIG. 13, as the first extension region EA1 is biased to one side (e.g., to a left region) in the first cell block BLK1, signal delay may occur in a signal applied to the gate electrodes 112 and 117 arranged in a region (e.g., a right region) relatively far from the first extension region EA1. On the other hand, as shown in FIG. 14, as the first extension region EA1 is divided into the first sub-extension region EA1a and the second sub-extension region EA1b, signal delay caused by bias of the extension region may be avoided.

In some implementations, each of the second cell block BLK2 and the third cell block BLK3 may not include a plurality of extension regions. For example, each of the second extension region EA2 and the third extension region EA3 is relatively adjacent to a central portion and is not biased to one side, so that signal delay may be avoided.

In some implementations, a length (e.g., the second length Le) of each of the sub-extension regions EA1a, EA1b, EA4a and EA4b may be the same as the length of the second extension region EA2 and/or the length of the third extension region EA3. For example, the number of first gate contacts 162 arranged in each of the sub-extension regions EA1a, EA1b, EA4a and EA4b may be the same as the number of first gate contacts 162 arranged in each of the second extension region EA2 and the third extension region EA3. For example, the plurality of first gate contacts 162 corresponding to the plurality of gate electrodes 112 and 117 may be arranged in each of the first sub-extension regions EA1a and the second sub-extension regions EA1b. In this case, two first gate contacts 162 may be arranged per each of the gate electrodes 112 and 117 in the first extension region EA1.

Referring to FIG. 15, in the semiconductor memory device according to some implementations, the length of each of the sub-extension regions EA1a, EA1b, EA4a and EA4b may be shorter than the length of each of the second and third extension regions EA2 and EA3.

For example, a third length Le1 of the first sub-extension region EA1a in the second direction X may be shorter than a fourth length Le2 of the second extension region EA2 in the second direction X and/or a fifth length Le3 of the second extension region EA2 in the second direction X. In some implementations, the number of first gate contacts 162 arranged in each of the first sub-extension region EA1a and the second sub-extension region EA1b may be less than the number of first gate contacts 162 arranged in each of the second extension region EA2 and the third extension region EA3.

For example, a sixth length Le4 of the third sub-extension region EA4a in the second direction X may be shorter than the fourth length Le2 of the second extension region EA2 in the second direction X and/or the fifth length Le3 of the second extension region EA2 in the second direction X. In some implementations, the number of first gate contacts 162 arranged in each of the third sub-extension region EA4a and the fourth sub-extension region EA4b may be less than the number of first gate contacts 162 arranged in each of the second extension region EA2 and the third extension region EA3.

In some implementations, each of the third length Le1 and the sixth length Le4 may be greater than half of the fourth length Le2 and/or half of the fifth length Le3. For example, the number of first gate contacts 162 arranged in each of the first extension region EA1 and the fourth extension region EA4 may be less than twice the number of first gate contacts 162 arranged in each of the second extension region EA2 and the third extension region EA3.

For example, one of the first gate contacts 162 may be arranged per portion of the plurality of gate electrodes 112 and 117 in the first extension region EA1. A portion of each of the gate electrodes 112 and 117, which is connected to one of the first gate contacts 162, may be connected to the first gate contact 162 in a region relatively adjacent to the central portion. As a portion of the gate electrodes 112 and 117 is not biased to one side, signal delay may be avoided.

Also, for example, two of the first gate contacts 162 may be arranged per other portion of the plurality of gate electrodes 112 and 117 in the first extension region EA1. One of the two first gate contacts 162 may be arranged in the first sub-extension region EA1a, and the other one of the two first gate contacts 162 may be arranged in the second sub-extension region EA1b. Accordingly, signal delay caused by bias of the extension region may be avoided.

In some implementations, the length of each of the first sub-extension region EA1a and the second sub-extension region EA1b may be shorter than the length of each of the third sub-extension region EA4a and the fourth sub-extension region EA4b. For example, the third sub-extension region EA4a and the fourth sub-extension region EA4b may be arranged farther from the second and third extension regions EA2 and EA3 than the first sub-extension regions EA1a and the second sub-extension region EA1b. In this case, the number of first gate contacts 162 arranged in each of the first sub-extension region EA1a and the second sub-extension region EA1b may be less than the number of first gate contacts 162 arranged in each of the third sub-extension region EA4a and the fourth sub-extension region EA4b.

Hereinafter, an electronic system including a semiconductor memory device according to example implementations will be described with reference to FIGS. 1 to 11, 12a, 12b, and 13 to 18.

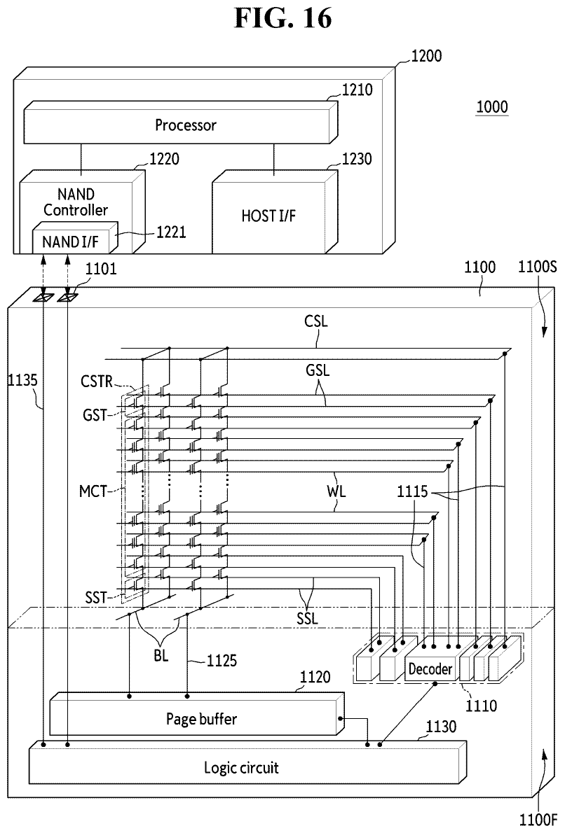

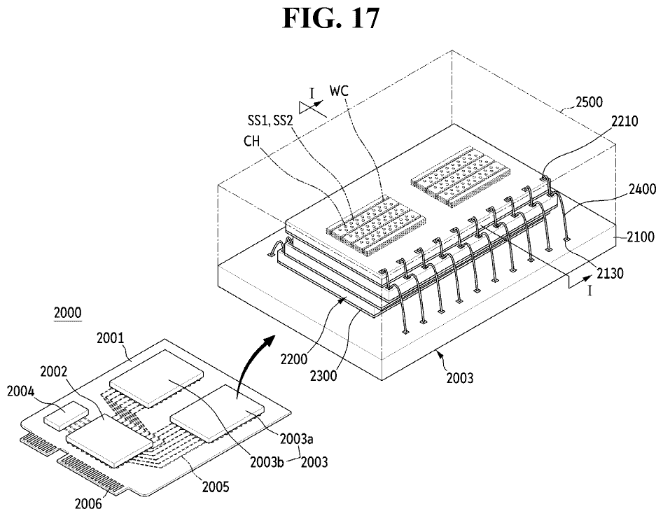

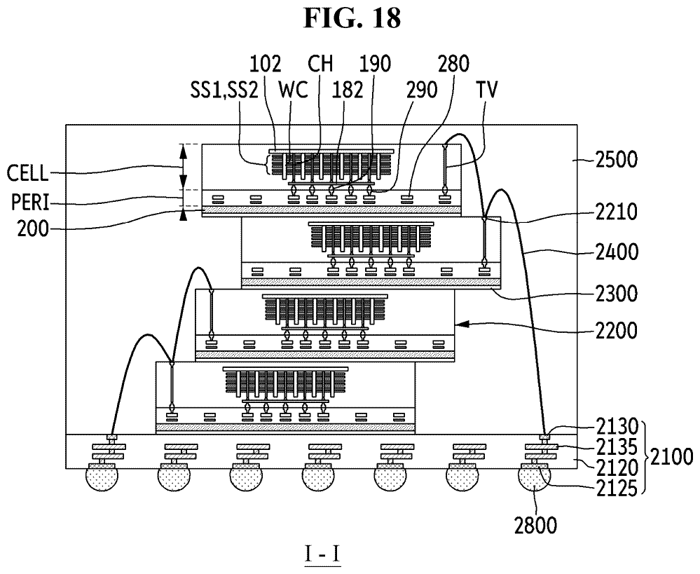

FIG. 16 is an example block diagram illustrating an electronic system according to some implementations. FIG. 17 is an example perspective view illustrating an electronic system according to some implementations. FIG. 18 is a schematic cross-sectional view taken along line I-I of FIG. 17. For convenience of description, redundant portions of those described above with reference to FIGS. 1 to 11, 12a, 12b, and 15 will be briefly described or omitted.

Referring to FIG. 16, an electronic system 1000 according to some implementations may include a semiconductor memory device 1100 and a controller 1200 electrically connected to the semiconductor memory device 1100. The electronic system 1000 may be a storage device including one or a plurality of semiconductor memory devices 1100 or an electronic device including the storage device. For example, the electronic system 1000 may be a solid state drive (SSD) device, a universal serial bus (USB), a computing system, a medical device or a communication device, which includes one or more semiconductor memory devices 1100.

The semiconductor memory device 1100 may be a non-volatile memory device (e.g., NAND flash memory device), and include, for example, at least one of the semiconductor memory devices described with reference to FIGS. 1 to 11, 12a, 12b, and 13 to 15. The semiconductor memory device 1100 may include a first structure 1100F and a second structure 1100S on the first structure 1100F.

The first structure 1100F may be a peripheral circuit structure that includes a decoder circuit 1110 (e.g., the row decoder 33 of FIG. 1), a page buffer 1120 (e.g., the page buffer 35 of FIG. 1) and a logic circuit 1130 (e.g., the control logic 37 of FIG. 1). For example, the first structure 1100F may correspond to the peripheral circuit structure PERI described above with reference to FIGS. 1 to 11, 12a, 12b, and 13 to 15.

The second structure 1100S may include a common source line CSL, a plurality of bit lines BL and a plurality of cell strings CSTR, which are described above with reference to FIG. 2. The cell strings CSTR may be connected to the decoder circuit 1110 through a plurality of word lines WL, at least one string selection line SSL and at least one ground selection line GSL. In addition, the cell strings CSTR may be connected to the page buffer 1120 through the bit lines BL. For example, the second structure 1100S may correspond to the cell structure CELL described above with reference to FIGS. 1 to 11, 12a, 12b, and 13 to 15.

In some implementations, the common source line CSL and the cell strings CSTR may be electrically connected to the decoder circuit 1110 through first connection wires 1115 extended from the first structure 1100F to the second structure 1100S.

In some implementations, the bit lines BL may be electrically connected to the page buffer 1120 through second connection wires 1125.

The semiconductor memory device 1100 may perform communication with the controller 1200 through an input/output pad 1101 electrically connected to the logic circuit 1130 (e.g., the control logic 37 of FIG. 1). The input/output pad 1101 may be electrically connected to the logic circuit 1130 through an input/output connection wire 1135 extended from the first structure 1100F to the second structure 1100S.

The controller 1200 may include a processor 1210, a NAND controller 1220 and a host interface 1230. In some implementations, the electronic system 1000 may include a plurality of semiconductor memory devices 1100, and in this case, the controller 1200 may control the plurality of semiconductor memory devices 1100.

The processor 1210 may control the overall operation of the electronic system 1000 including the controller 1200. The processor 1210 may operate in accordance with predetermined firmware, and may access the semiconductor memory device 1100 by controlling the NAND controller 1220. The NAND controller 1220 may include a NAND interface 1221 that processes communication with the semiconductor memory device 1100. A control command for controlling the semiconductor memory device 1100, data to be written in memory cell transistors MCT of the semiconductor memory device 1100, data to be read from the memory cell transistors MCT of the semiconductor memory device 1100, etc. may be transmitted through the NAND interface 1221. The host interface 1230 may provide a communication function between the electronic system 1000 and an external host. When the control command is received from the external host through the host interface 1230, the processor 1210 may control the semiconductor memory device 1100 in response to the control command.

Referring to FIGS. 17 and 18, an electronic system according to some implementations may include a main board 2001, a main controller 2002 packaged on the main board 2001, one or more semiconductor packages 2003 and a DRAM 2004. The semiconductor package 2003 and the DRAM 2004 may be connected to the main controller 2002 by wiring patterns 2005 formed in the main board 2001.

The main board 2001 may include a connector 2006 that includes a plurality of pins coupled to the external host. The number and arrangement of the plurality of pins in the connector 2006 may be varied depending on the communication interface between the electronic system 2000 and the external host. In some implementations, the electronic system 2000 may perform communication with the external host in accordance with any one of interfaces such as a Universal Serial Bus (USB), a Peripheral Component Interconnect Express (PCI-Express), Serial Advanced Technology Attachment (SATA) and M-Phy for Universal Flash Storage (UFS). In some implementations, the electronic system 2000 may operate by a power source supplied from the external host through the connector 2006. The electronic system 2000 may further include a power management integrated circuit (PMIC) that distributes the power source supplied from the external host to the main controller 2002 and the semiconductor package 2003.

The main controller 2002 may write data in the semiconductor package 2003 or read the data from the semiconductor package 2003, and may improve the operating speed of the electronic system 2000.

The DRAM 2004 may be a buffer memory for mitigating a speed difference between the semiconductor package 2003 that is a data storage space and the external host. Also, the DRAM 2004 included in the electronic system 2000 may operate as a kind of a cache memory, and may provide a space for temporarily storing data in a control operation for the semiconductor package 2003. When the DRAM 2004 is included in the electronic system 2000, the main controller 2002 may further include a DRAM controller for controlling the DRAM 2004, in addition to the NAND controller for controlling the semiconductor package 2003.

The semiconductor package 2003 may include a first semiconductor package 2003a and a second semiconductor package 2003b, which are spaced apart from each other. Each of the first semiconductor package 2003a and the second semiconductor package 2003b may be a semiconductor package that includes a plurality of semiconductor chips 2200. Each of the first semiconductor package 2003a and the second semiconductor package 2003b may include a package substrate 2100, semiconductor chips 2200 on the package substrate 2100, adhesive layers 2300 arranged on a lower surface of each of the semiconductor chips 2200, a connection structure 2400 for electrically connecting the semiconductor chips 2200 with the package substrate 2100, and a molding layer 2500 covering the semiconductor chips 2200 and the connection structure 2400 on the package substrate 2100.

The package substrate 2100 may be a printed circuit board that includes package upper pads 2130. Each semiconductor chip 2200 may include an input/output pad 2210. The input/output pad 2210 may correspond to the input/output pad 1101 of FIG. 16.

In some implementations, the connection structure 2400 may be a bonding wire for electrically connecting the input/output pad 2210 with the package upper pads 2130. Therefore, in each of the first semiconductor package 2003a and the second semiconductor package 2003b, the semiconductor chips 2200 may be electrically connected to each other in a bonding wire manner and may be electrically connected to the package upper pads 2130 of the package substrate 2100. In some implementations, in each of the first semiconductor package 2003a and the second semiconductor package 2003b, the semiconductor chips 2200 may be electrically connected to each other by a connection structure that includes a through silicon via TSV, instead of the connection structure 2400 of the bonding wire manner.

In some implementations, the main controller 2002 and the semiconductor chips 2200 may be included in one package. In some implementations, the main controller 2002 and the semiconductor chips 2200 may be packaged on a separate interposer substrate different from the main board 2001, and the main controller 2002 may be connected with the semiconductor chips 2200 by a wire formed in the interposer substrate.

In some implementations, the package substrate 2100 may be a printed circuit board. The package substrate 2100 may include a package substrate body portion 2120, package upper pads 2130 arranged on an upper surface of the package substrate body portion 2120, lower pads 2125 arranged on a lower surface of the package substrate body portion 2120 or exposed through the lower surface and internal wires 2135 electrically connecting the package upper pads 2130 with the lower pads 2125 inside the package substrate body portion 2120. The package upper pads 2130 may be electrically connected to the connection structures 2400. The lower pads 2125 may be connected to the wiring patterns 2005 of the main board 2001 of the electronic system 2000 through conductive connectors 2800 as shown in FIG. 18.

In the electronic system 2000 according to some implementations, each of the semiconductor chips 2200 may include the semiconductor memory device described with reference to FIGS. 1 to 11, 12a, 12b, and 13 to 15. For example, each of the semiconductor chips 2200 may include a memory cell structure CELL and a peripheral circuit structure PERI. Illustratively, the memory cell structure CELL may include a first substrate 102, a first stacked structure SS1, a second stacked structure SS2, a channel structure CH, a cutting pattern WC, and a first wiring structure 180, which are described with reference to FIGS. 1 to 11, 12a, 12b, and 13 to 15. The peripheral circuit structure PERI may include a second substrate 200 and a second wiring structure 280. The memory cell structure CELL and the peripheral circuit structure PERI may be bonded to each other through the first bonding metal 190 and the second bonding metal 290.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

In concluding the detailed description, those skilled in the art will appreciate that many variations and modifications may be made to the preferred implementations without substantially departing from the principles of the present disclosure. Therefore, the disclosed preferred implementations of the disclosure are used in a generic and descriptive sense only and not for purposes of limitation.

What is claimed is:

1. A semiconductor memory device comprising:
a substrate including a cell array region and an extension region adjacent to the cell array region;
a stacked structure on the substrate, the stacked structure including a plurality of gate electrodes spaced apart from each other in a first direction crossing an upper surface of the substrate;
a channel structure on the cell array region, the channel structure crossing the plurality of gate electrodes;
a plurality of first gate contacts on the extension region, the plurality of first gate contacts corresponding to the plurality of gate electrodes; and
a cutting pattern configured to cut the stacked structure,
wherein each of the plurality of first gate contacts is connected to a corresponding one of the plurality of gate electrodes by passing at least partially through remaining ones of the plurality of gate electrodes,
wherein the cutting pattern comprises a first extension portion extending in a second direction crossing the first direction, and a bending portion extending from the first extension portion in a third direction crossing the first direction and the second direction,
wherein the extension region and the bending portion are arranged along the second direction, and
wherein the extension region is between the cell array region and the first extension portion in the third direction.

2. The semiconductor memory device of claim 1, comprising an insulating spacer surrounding sides of the first gate contacts.

3. The semiconductor memory device of claim 1, wherein the plurality of first gate contacts are arranged in a line along the second direction.

4. The semiconductor memory device of claim 1, wherein the cutting pattern comprises a second extension portion extending in the second direction,
wherein the bending portion connects the first extension portion with the second extension portion.

5. The semiconductor memory device of claim 1, comprising a wiring structure on the stacked structure,
wherein the wiring structure comprises a conductive line extending in the third direction and connected to the channel structure.

6. The semiconductor memory device of claim 5, wherein the wiring structure comprises a connection pattern connected to each of the first gate contacts.

7. The semiconductor memory device of claim 1, wherein each of the first gate contacts passes through the substrate.

8. The semiconductor memory device of claim 1, wherein the plurality of gate electrodes comprise a string selection line and a string separation pattern, and
wherein the string separation pattern is on the cell array region and extends in the second direction to cut the string selection line.

9. The semiconductor memory device of claim 8, wherein the substrate comprises a space region adjacent to the cell array region in the second direction, and comprises a second gate contact on the space region, the second gate contact being connected to the string selection line.

10. The semiconductor memory device of claim 1, comprising a peripheral circuit structure comprising a peripheral circuit board and a peripheral circuit element on the peripheral circuit board,
wherein the substrate comprises a first surface facing the peripheral circuit structure and a second surface opposite to the first surface, and
wherein the stacked structure is on the first surface.

11. The semiconductor memory device of claim 10, wherein the substrate comprises a space region adjacent to the cell array region in the second direction, and
comprises a through via on the space region, the through via connecting each of the first gate contacts with the peripheral circuit element by passing through the substrate and the stacked structure.

12. A semiconductor memory device comprising a first cell block and a second cell block that are adjacent to each other, the semiconductor memory device comprising:
a substrate including a first cell array region and a first extension region inside the first cell block, and including a second cell array region and a second extension region inside the second cell block;
a stacked structure on the substrate, the stacked structure comprising a plurality of gate electrodes spaced apart from each other in a first direction crossing an upper surface of the substrate;
a channel structure on each of the first cell array region and the second cell array region, the channel structure crossing the plurality of gate electrodes;
a plurality of gate contacts on the first extension region and the second extension region, the plurality of gate contacts corresponding to the plurality of gate electrodes; and
a cutting pattern separating the stacked structure of the first cell block from the stacked structure of the second cell block,
wherein each of the plurality of gate contacts is connected to a corresponding one of the plurality of gate electrodes by passing through at least some of the plurality of gate electrodes,
wherein the first cell array region and the second cell array region extend in a second direction crossing the first direction, and are arranged in a third direction crossing the first direction and the second direction,
wherein the first extension region is between the first cell array region and the second cell array region in the third direction, and
wherein the first extension region and the second extension region are arranged along the second direction.

13. The semiconductor memory device of claim 12, comprising an insulating spacer surrounding sides of the plurality of gate contacts.

14. The semiconductor memory device of claim 12, wherein a first length of the first cell block in the second direction is greater than a second length of the first extension region in the second direction.

15. The semiconductor memory device of claim 12, wherein the plurality of gate contacts are arranged in a line along the second direction.

16. The semiconductor memory device of claim 12, wherein the cutting pattern comprises a first extension portion extending in the second direction between the first extension region and the second cell array region, a second extension portion extending in the second direction between the first cell array region and the second extension region, and a bending portion extending in the third direction to connect the first extension portion with the second extension portion.

17. The semiconductor memory device of claim 12, wherein the channel structure comprises a semiconductor film crossing the plurality of gate electrodes and a data storage film between the semiconductor film and the plurality of gate electrodes.

18. The semiconductor memory device of claim 12, comprising a support pattern on each of the first and second extension regions, the support pattern crossing the plurality of gate electrodes.

19. An electronic system comprising:
a main board;
a semiconductor memory device on the main board, the semiconductor memory device comprising a plurality of cell blocks; and
a controller on the main board, the controller being electrically connected to the semiconductor memory device,
wherein the semiconductor memory device comprises:
a substrate comprising a cell array region and an extension region inside the cell blocks;
a stacked structure comprising a plurality of gate electrodes spaced apart from each other in a first direction crossing an upper surface of the substrate;
a channel structure on the cell array region, the channel structure crossing the plurality of gate electrodes;
a plurality of gate contacts on the extension region, the plurality of gate contacts corresponding to the plurality of gate electrodes; and
a cutting pattern configured to cut the stacked structure,
wherein each of the gate contacts is connected to a corresponding one of the plurality of gate electrodes by passing at least partially through remaining ones of the plurality of gate electrodes,
wherein a first length of the cell array region in a second direction crossing the first direction is greater than a second length of the extension region in the second direction, and
wherein in each of the cell blocks, the cell array region and the extension region are arranged along a third direction crossing the first and second directions.

20. The electronic system of claim 19, wherein the plurality of gate contacts are arranged in a line along the second direction.
